(19) United States
(12) Patent Application Publication
(10) Pub. No.: US 2008/0054443 A1
(43) Pub. Date: Mar. 6, 2008

(54) Carrier board structure with semiconductor chip embedded therein

(76) Inventor: Chao-Wen Shih, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/508,708

(22) Filed: Aug. 23, 2006

(51) Int. Cl. H01L 23/04

(52) U.S. Cl. 257/698

(57) ABSTRACT

A carrier board structure with semiconductor chip embedded therein is proposed. The carrier board structure includes a carrier board having a first surface and a second surface opposed to the first surface, wherein the carrier board including at least one cavity having a chamfer. A semiconductor chip can be easily disposed in the cavity by the chamfer, and an adhesion material can be evenly filled in the cavity by the chamfer, so as to avoid generating air bubbles, voids and reduce stress.

### CROSS-REFERENCE TO RELATED APPLICATIONS

The present application is related to co-pending Taiwan Application No. 095118215, filed on May 23, 2006.

### FIELD OF THE INVENTION

The present invention relates generally to a carrier board structure, and more particularly to a carrier board structure with a semiconductor chip embedded therein.

### DESCRIPTION OF RELATED ART

With rapid development of semiconductor package technology, there have been developed various kinds of package structures for semiconductor devices. To form a semiconductor device package structure, a semiconductor chip is typically mounted to and electrically connected with a package substrate or a lead frame and then encapsulated by an encapsulant. In BGA semiconductor packaging, a semiconductor chip is mounted to and electrically connected to a package substrate. The back side of the package substrate has an array solder balls formed through a self-alignment technology, by which electrical connection can be made to external device.

Although such a package structure enables a higher pin count per unit area, in high frequency or high speed application, its long electrical conducting path leads to high resistance and prevents further improvement of electrical characteristic, thereby limiting the use of such a package structure.

To overcome the above drawbacks, embedded chip technology has been proposed for shortening the electrical conducting path, decreasing signal loss and signal deformation, and improving performance in high speed application.

FIGS. 1A to 1D show a fabrication process of a conventional carrier board with a semiconductor chip embedded therein. First, a carrier board 10 having a first surface 10a and a second surface 10b opposed to the first surface 10a is provided. The carrier board 10 can be a dielectric board, a metal board, or a single or multi-layer circuit board. At least a cavity 100 is formed in the carrier board 10, as shown in FIG. 1A. Next, at least a semiconductor chip 11 having a plurality of electrode pads 110 is disposed in the cavity 100 of the carrier board 10, as shown in FIG. 1B. An adhesion board (not shown) can be disposed on the second surface 10b of the carrier board 10 and removed in subsequent process. An adhesion material 12 is filled in the cavity 100 of the carrier board 10 and cured so as to fix the semiconductor chip 11 in the cavity 100 of the carrier board 10, as shown in FIG. 1C. Subsequently, a circuit build-up process is performed on the first and second surfaces 10a, 10b of the carrier board 10. As a result, at least a first dielectric layer 13a and a second dielectric layer 13b can be formed on the first and second surfaces 10a, 10b of the carrier board 10 in sequence, and a first circuit layer and a second circuit layer 14a, 14b are respectively formed on the first and second dielectric layers 13a, 13b. The first circuit layer 14a is electrically connected to the electrode pads 110 of the semiconductor chip 11 through the conductive blind vias 140 formed in the first dielectric layer 13a. A plating through hole 142 is formed in the carrier board 10 for electrically connecting the first and second circuit layers 14a, 14b, as shown in FIG. 1D.

FIG. 2 shows another conventional a carrier board structure with a semiconductor chip embedded therein. A cavity 100′ is formed in the carrier board 10. A semiconductor chip 11 with a plurality of electrode pads 110 is disposed in the cavity 100′. An adhesion material 12 is filled in the cavity 100′ and cured so as to fix the semiconductor chip 11 in the cavity 100′. Subsequently, a circuit build-up process is performed on surface of the carrier board 10 so as to form a circuit build-up structure with at least a dielectric layer 13 and a circuit layer 14. The circuit layer 14 is electrically connected to the electrode pads 110 of the semiconductor chip 11 through blind vias 140 formed in the dielectric layer 13.

The carrier board with a semiconductor chip embedded therein fabricated through the above fabrication process can shorten the electrical conducting path, decrease signal loss and signal deformation, improve performance in high frequency application, thereby overcoming the above-mentioned drawbacks. However, the vertical cavity of the same size from top to bottom in the above structures makes it difficult to dispose the semiconductor chip in the cavity.

In addition, it is difficult to sufficiently and evenly fill the narrow slit between the semiconductor chip and the cavity by the adhesion material. As a result, the air and voids can be left in the cavity, and the residual voids will cause popcorn phenomenon in subsequent heat circulation process, thereby seriously affecting the process reliability.

Furthermore, since there is small distance between the lateral sides of the semiconductor chip and the cavity, thermal stress generated from different coefficients of thermal expansion can cause the lateral side of the cavity to press against the lateral side of the semiconductor chip and thereby damage the semiconductor chip. Also, too big thermal stress can lead to delamination of the dielectric layer from the periphery of the cavity, thereby adversely affecting the quality of the carrier board structure with a semiconductor chip embedded therein.

Therefore, there exists a need to provide a new carrier board structure with a semiconductor chip embedded therein so as to overcome the above drawbacks.

### SUMMARY OF THE INVENTION

Accordingly, an objective of the present invention is to provide a carrier board structure with a semiconductor chip embedded therein, which can facilitate disposing the semiconductor chip in a cavity of the carrier board.

Another objective of the present invention is to provide a carrier board structure with a semiconductor chip embedded therein, which can prevent residual air and voids from being generated in the cavity.

A further objective of the present invention is to provide a carrier board structure with a semiconductor chip embedded therein, which can protect the semiconductor chip embedded in the carrier board from being influenced by thermal stress.

Still another objective of the present invention is to provide a carrier board structure with a semiconductor chip embedded therein, which can avoid the problem of having too much thermal stress on the periphery of the semiconductor chip and the cavity and disfavoring the subsequent circuit build-up process.

In order to attain the above and other objectives, a carrier board structure with a semiconductor chip embedded therein is proposed, which comprises: a carrier board having a first surface and a second surface opposed to the first surface, the carrier board comprising at least a cavity having a chamfer; at least a semiconductor chip disposed in the cavity, the semiconductor chip having an active surface with a plurality of electrode pads and a non-active surface opposed to the active surface; and an adhesion material filled in a gap between the cavity and the semiconductor chip.

In a preferred embodiment, the cavity penetrates the first and second surfaces of the carrier board. The chamfer of the cavity can be a full chamfer or a half chamfer. The carrier board structure of the present invention can further comprise a first dielectric layer formed on the first surface of the carrier board and the active surface of the semiconductor chip, and a second dielectric layer formed on the second surface of the carrier board and the non-active surface of the semiconductor chip. A circuit build-up structure can further be formed on one of the surfaces of the first and second dielectric layers, wherein a plurality of conductive structures are formed in the circuit build-up structure to electrically connect with the electrode pads of the semiconductor chip, and a plurality of electrically connecting pads are formed on a surface of the circuit build-up structure.

Compared with the prior art, the cavity of the carrier board structure of the present invention has a chamfer, which not only facilitates disposing the semiconductor chip in the cavity, but also allows the adhesion material to be evenly and sufficiently filled in the cavity so as to avoid residual air and voids in the cavity. Meanwhile, the semiconductor chip can be protected from being influenced by thermal stress generated from different coefficients of thermal expansion.

### BRIEF DESCRIPTION OF DRAWINGS

FIGS. 1A to 1D show a conventional fabrication process of a carrier board structure with a semiconductor chip embedded therein;

FIG. 2 is a sectional view of another conventional carrier board structure with a semiconductor chip embedded therein;

FIGS. 3A to 3E show a fabrication process of a carrier board structure with a semiconductor chip embedded therein according to a first embodiment of the present invention; and

FIG. 4 is a sectional view of a carrier board structure with a semiconductor chip embedded therein according to a second embodiment of the present invention.

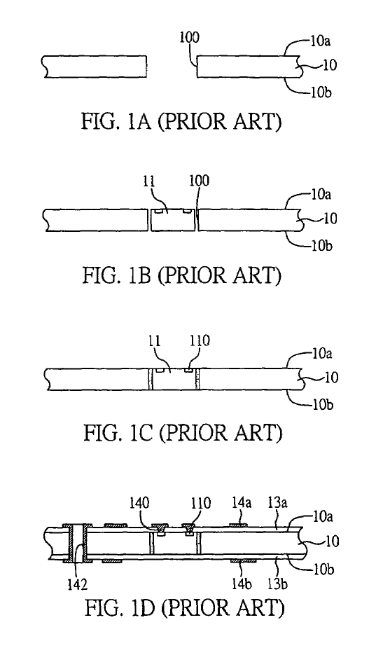

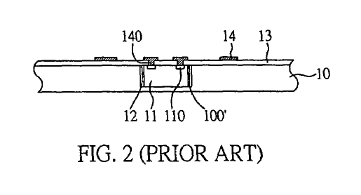

### DETAILED DESCRIPTION OF THE INVENTION

The present invention relates generally to a carrier board structure, and more particularly to a carrier board structure with a semiconductor chip embedded therein. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

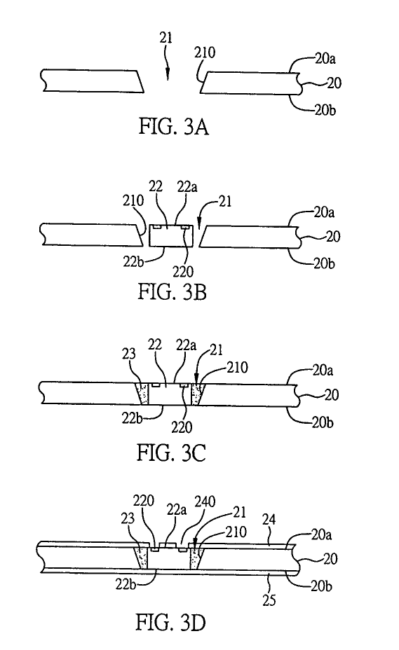

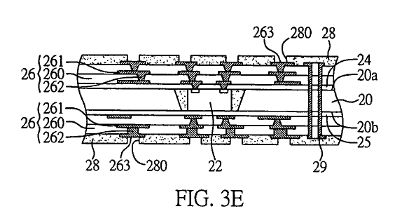

FIGS. 3A to 3E show a fabrication process of a carrier board structure with a semiconductor chip embedded therein according to a first embodiment of the present invention.

As shown in FIG. 3A, a carrier board 20 with a first surface 20a and a second surface 20b opposed to the first surface 20a is provided and a circular or rectangular cavity 21 penetrating through the first and second surfaces 20a and 20b of the carrier board 20 is formed in the carrier board 20. The cavity 21 has a chamfer 210, and the chamfer 210 is a full chamfer. In the present embodiment, the cavity 21 can be formed by cutting, punching or laser ablating application.

As shown in FIG. 3B, at least a semiconductor chip 22 is disposed in the cavity 21. Due to the chamfer 210, the semiconductor chip 22 is easy to be disposed in the cavity 21. An adhesion board (not shown) can be disposed on the second surface 20b of the carrier board 20 and can be removed in subsequent processes. The semiconductor chip 22 has an active surface 22a and a non-active surface 22b opposed to the active surface 22a, wherein the active surface 22a of the semiconductor chip 22 has a plurality of electrode pads 220. In the present embodiment, the semiconductor chip 22 is disposed in the cavity 21 through its non-active surface 22b.

As shown in FIG. 3C, an adhesion material 23 such as a resin material or a colloid is filled in the gap between the cavity 21 and the semiconductor chip 22. After the adhesion material 23 is cured, the semiconductor chip 22 is fixed in the cavity 21. In the present embodiment, the chamfer 210 of the cavity 21 makes the gap between the cavity 21 and the semiconductor chip 22 have a funnel shape with a wider cavity at the top thereof. As a result, the adhesion material 23 can smoothly flow into the cavity 21 and firmly and evenly fill the cavity 21 so as to eliminate the popcorn problem during subsequent heat circulation process caused by residual air or voids. Meanwhile, since there is a much big distance between the lateral sides of the semiconductor chip 22 and the cavity 21, thermal stress generated by different coefficients of thermal expansion can be prevented from causing the lateral side of the cavity 21 to press against the lateral side of the semiconductor chip 22, thereby avoiding the damage of the semiconductor chip 22. Also, too big thermal stress between the lateral sides of the semiconductor chip 22 and the cavity 21 can be avoided so as to facilitate the subsequent circuit build-up process.

As shown in FIG. 3D, a first dielectric layer 24 is formed on the first surface 20a of the carrier board 20 and the active surface 22a of the semiconductor chip 22, and a second dielectric layer 25 is formed on the second surface 20b of the carrier board 20 and the non-active surface 22b of the semiconductor chip 22. The first dielectric layer 24 has a plurality of openings 240 so as to expose the electrode pads 220 of the semiconductor chip 22. The first and second dielectric layers 24,25 may be made of materials such as Epoxy resin, Polyimide, Cyanate ester, Glass fiber, BT (Bismaleimide triazine), PP (Polypropylene), ABF and a mixture of epoxy resin and glass fiber.

As shown in FIG. 3E, a circuit build-up structure 26 is further formed on surfaces of the first dielectric layer 24 and the second dielectric layer 25. The circuit build-up structure 26 comprises a dielectric layer 260, a circuit layer 261 stacked on the dielectric layer 260 and conductive structures 262 formed in the dielectric layer 260. Parts of the conductive structures 262 is electrically connected to the electrode pads 220 of the semiconductor chip 22 and a plurality of electrically connecting pads 263 are formed on surface of the circuit build-up structure 26. The circuit build-up structure 26 respectively on the first and second dielectric layers 24, 25 is electrically connected through at least a plating through hole 29.

A solder mask layer 28 is formed on surface of the circuit build-up structure 26, which has a plurality of openings 280 so as to expose the electrically connecting pads 263 on the surface of the circuit build-up structure 26.

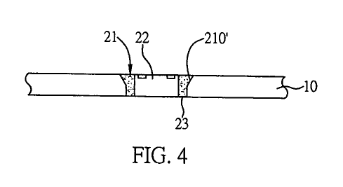

Referring to FIG. 4, another embodiment of the present invention is shown. The chamfer 210′ of the cavity 21 of the present embodiment is a half chamfer, that is, instead of obliquely cutting the entire cavity 21 as a full chamfer, only a part of the cavity is obliquely cut and the other part of the cavity is remained at vertical state. Through the half chamfer, the semiconductor chip 22 can also be easily disposed in the cavity 21 and the adhesion material 23 can be evenly and firmly filled in the cavity 21 without the generation of air bubble or voids. Thermal stress can be prevented from causing the lateral side of the cavity 21 to press against the lateral side of the semiconductor chip 22 so as to avoid the damage of the semiconductor chip 22. Also, too big thermal stress between the lateral sides of the semiconductor chip 22 and the cavity 21 can be avoided so as to facilitate the subsequent circuit build-up process.

Through the above fabrication process, a carrier board structure with a semiconductor chip embedded therein is obtained, which comprises: a carrier board 20 having at least an cavity 21 with a chamfer 210, at least a semiconductor chip 22 disposed in the cavity 21, and an adhesion material 23 filled the gap between the cavity 21 and the semiconductor chip 22 so as to fix the semiconductor chip 22 in the cavity 21. The carrier board 20 has a first surface 20a and a second surface 20b opposed to the first surface 20a, and the cavity 21 of the circuit board 20 penetrates through the first and second surfaces 20a and 20b. The chamfer 210 of the cavity 21 can be a full chamfer or a half chamfer. The semiconductor chip 22 has an active surface 22a and a non-active surface 22b, wherein the active surface 22a of the semiconductor chip 22 has a plurality of electrode pads 220.

In the present embodiment, the carrier board structure further comprises a first dielectric layer 24 formed on the first surface 20a of the carrier board 20 and the active surface 22a of the semiconductor chip 22, and a second dielectric layer formed on the second surface 20b of the carrier board 20 and the non-active surface 22b of the semiconductor chip 22. In addition, a circuit build-up structure 26 is formed on the first and second dielectric layers 24,25. A solder mask layer 28 is formed on surface of the circuit build-up layer 26. The solder mask layer 28 has a plurality of openings 280 so as to expose the electrically connecting pads 263 formed on surface of the circuit build-up structure 26.

Through the chamfer formed in the cavity of the carrier board, the semiconductor chip can easily be disposed in the cavity.

In addition, the funnel-shaped chamfer of the cavity allows the adhesion material to be firmly and evenly filled in the cavity of the carrier board so as to avoid the generation of air bubble or voids caused by uneven filling or insufficient filling of the adhesion material. As a result, the popcorn problem caused in a subsequent heat circulation process by the residual air and voids can be avoided and accordingly the process reliability is increased.

Furthermore, the chamfer of the cavity leads to a big distance between the lateral side of the semiconductor chip and the lateral side of the cavity, which is helpful to prevent the thermal stress generated by different coefficients of thermal expansion from damaging the semiconductor chip by making the lateral side of the cavity press against the lateral side of the semiconductor chip.

Moreover, the chamfer of the cavity can prevent the happening of delamination of the dielectric layer from the cavity because of big thermal stress between the lateral side of the semiconductor chip and the lateral side of the cavity.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A carrier board structure with a semiconductor chip embedded therein, comprising:
a carrier board having a first surface and a second surface opposed to the first surface, the carrier board comprising at least a cavity having a chamfer;
at least a semiconductor chip disposed in the cavity, the semiconductor chip having an active surface with a plurality of electrode pads and a non-active surface opposed to the active surface; and
an adhesion material filled in a gap between the cavity and the semiconductor chip.

2. The carrier board structure of claim 1, wherein the carrier board is one of an insulating board, a metal board and a circuit board having wires.

3. The carrier board structure of claim 1, wherein the cavity penetrates through the first and second surfaces of the carrier board.

4. The carrier board structure of claim 3, wherein the chamfer of the cavity is one of a full chamfer and a half chamfer.

5. The carrier board structure of claim 3, further comprising a first dielectric layer formed on the first surface of the carrier board and the active surface of the semiconductor chip, and a second dielectric layer formed on the second surface of the carrier board and the non-active surface of the semiconductor chip.

6. The carrier board structure of claim 5, further comprising a circuit build-up structure formed on one of the surfaces of the first and second dielectric layers, wherein a plurality of conductive structures are formed in the circuit build-up structure to electrically connect with the electrode pads of the semiconductor chip, and a plurality of electrically connecting pads are formed on a surface of the circuit build-up structure.

7. The carrier board structure of claim 6, further comprising a solder mask layer formed on the surface of the circuit build-up structure, the solder mask layer having a plurality of openings for exposing the electrically connecting pads of the circuit build-up structure.

8. The carrier board structure of claim 6, wherein the circuit build-up structure comprises a dielectric layer, a circuit layer stacked on the dielectric layer and conductive structures formed in the dielectric layer.

9. The carrier board structure of claim 1, wherein the cavity is one of a circular cavity and a rectangular cavity.

10. The carrier board structure of claim 1, wherein the adhesion material is one of a resin material and a colloid.
